(19) United States
(12) Patent Application Publication
(10) Pub. No.: US 2016/0269658 A1
(43) Pub. Date: Sep. 15, 2016

(54) Image Sensors and Image Processing Systems Including the Image Sensors

(71) Applicant: Samsung Electronics Co., Ltd., Suwon-si (KR)

(72) Inventors: Won Ho Choi, Suwon-si (KR); Young Kyun JEONG, Hwaseong-si (KR); Jin-Kyeong HEO, Hwaseong-si (KR); Chang Eun KANG, Gimpo-si (KR); Ji Hun SHIN, Seongnam-si (KR)

(21) Appl. No.: 15/067,783

(22) Filed: Mar. 11, 2016

(30) Foreign Application Priority Data
Mar. 12, 2015 (KR) 10-2015-0034581

(51) Int. Cl. H04N 5/355; H04N 5/347; H01L 27/146; H04N 5/378

(52) U.S. Cl. CPC H04N 5/35554; H04N 5/378; H04N 5/347; H01L 27/14623; H01L 27/14621; H01L 27/14627

(57) ABSTRACT

An image sensor may include a plurality of pixels, a plurality of sub-pixel groups, respective ones of the sub-pixel groups including at least two pixels among the plurality of pixels, and an analog-to-digital converter configured to perform analog-to-digital conversion on pixel signals output from the plurality of sub-pixel groups and configured to output digital pixel signals responsive to the analog-to-digital conversion. The at least two pixels may have different saturation times.

### CROSS-REFERENCE TO RELATED APPLICATION

This application claims the benefit of Korean Patent Application No. 10-2015-0034581, filed on Mar. 12, 2015, in the Korean Intellectual Property Office, the entire contents of which are incorporated herein by reference.

### BACKGROUND

The inventive concepts relate to image sensors and image processing systems including the same, and more particularly, to image sensors having a wide dynamic range and image processing systems including the same.

An image sensor is a device that converts an optical image into an electrical signal. The image sensor is used in a digital camera or other image processing systems. The image sensor includes a plurality of pixels.

Each of the plurality of pixels may include a photoelectric conversion device that converts an optical image into an electrical signal, and an additional circuit that converts the electrical signal into digital data.

The quality of the image sensor may be evaluated by various factors. The various factors can include a dynamic range, sensitivity, responsivity, uniformity, shuttering, a speed, noise, etc.

In particular, the dynamic range may be used to obtain image data without loss in an environment in which a low light level image and a high light level image are present. For example, an image sensor may have a wide dynamic range to prevent a decrease in a recognition rate caused by either a backlight situation occurring when a user goes out to a light place from a dark place or image blurring occurring at night due to sudden and strong light. When the image sensor does not have a wide dynamic range, an image of an object included in image data may be difficult to recognize.

Although a dynamic range may be expanded by controlling operating voltages to be applied to pixels or controlling exposure times of pixels, such operations may require additional circuits.

### SUMMARY

According to aspects of the inventive concepts, image sensors may include a plurality of pixels, a plurality of sub-pixel groups, respective ones of the sub-pixel groups including at least two pixels among the plurality of pixels, and an analog-to-digital converter configured to perform analog-to-digital conversion on pixel signals output from the plurality of sub-pixel groups and configured to output digital pixel signals. The at least two pixels may have different saturation times.

In some example embodiments, the respective ones of the plurality of sub-pixel groups may include a first pixel and a second pixel, and a first light-shielding film may be in a portion of the first pixel.

In some example embodiments, the first pixel may have a first saturation time longer than a second saturation time of the second pixel.

In some example embodiments, the first and second pixels may further include a photoelectric conversion device, a color filter on the photoelectric conversion device, and a micro-lens on the color filter. The first light-shielding film may be between the color filter and the photoelectric conversion device of the first pixel.

In some example embodiments, the first light-shielding film may have an area corresponding to 50% of an area of the photoelectric conversion device.

In some example embodiments, the respective ones of the plurality of sub-pixel groups may include four pixels, and a light-shielding film may be in a portion of at least two pixels among four pixels.

In some example embodiments, a first light-shielding film may be on a first pixel of the four pixels and a second light-shielding film may be on a second pixel of the four pixels. The first pixel may have a longer first saturation time longer than a second saturation time of the second pixel, and the second saturation time of the second pixel may be longer than saturation times of a third pixel and a fourth pixel of the four pixels.

In some example embodiments, each of the four pixels further may include a photoelectric conversion device, a color filter on the photoelectric conversion device, and a micro-lens on the color filter. The first light-shielding film may be between the color filter and the photoelectric conversion device of the first pixel, and the second light-shielding film may be between the color filter and the photoelectric conversion device of the second pixel.

In some example embodiments, the first light-shielding film may have a first area corresponding to 75% of an area of the photoelectric conversion device of the first pixel, and the second light-shielding film may have a second area corresponding to 50% of an area of the photoelectric conversion device of the second pixel.

According to other aspects of the inventive concepts, an image processing system may include an image sensor and an image signal processor configured to control the image sensor. The image sensor may include a plurality of pixels arranged in a plurality of row lines, a plurality of sub-pixel groups, wherein respective ones of the sub-pixel groups may include at least two pixels among the plurality of pixels, and an analog-to-digital converter configured to perform analog-to-digital conversion on pixel signals output from the plurality of sub-pixel groups and configured output digital pixel signals responsive to the analog-to-digital conversion. The at least two pixels may include a first pixel and a second pixel having different saturation times.

In some example embodiments, a first light-shielding film may be in a portion of the first pixel.

In some example embodiments, the first pixel may have a first saturation time that is longer than a second saturation time of the second pixel.

In some example embodiments, the image signal processor may receive the digital pixel signals from the analog-to-digital converter, may combine first digital pixel signals and second digital pixel signals corresponding to the first and second pixels respectively belonging to a sub-pixel group corresponding to one row line, and may output a result of combining the digital pixel signals.

In some example embodiments, the respective ones of the plurality of sub-pixel groups may include four pixels, and a light-shielding film may be in a portion of at least two pixels among the four pixels.

In some example embodiments, a first light-shielding film and a second light-shielding film may be respectively on a first pixel and a second pixel of the four pixels. A first area of the first light-shielding film may be greater than a second area of the second light-shielding film. The first pixel may have a first saturation time longer than a second saturation time of the second pixel. The second saturation time of the second pixel is longer than saturation times of a third pixel and a fourth pixel of the four pixels.

According to other aspects of the inventive concepts, an image processing system may include an image sensor comprising a pixel array including a plurality of pixels and a digital signal processor configured to receive image data from the image sensor and output an image signal. The plurality of pixels in the pixel array may include a first pixel type including a light-shielding film and a second pixel type free of a light-shielding film. The digital signal processor may be configured to synthesize respective signals from the first pixel type and the second pixel type to output the image signal.

In some example embodiments, the first pixel type may have a first saturation time that is greater than a second saturation time of the second pixel type.

In some example embodiments, synthesizing the respective signals from the first pixel type and the second pixel type may include adding respective digital pixel signals output from the first pixel type and the second pixel type.

In some example embodiments, the image processing system may further include a first sub-pixel group of the pixel array. The first sub-pixel group may include a pixel of the first pixel type and a pixel of the second pixel type. The pixel of the first pixel type and the pixel of the second pixel type may be in a same row or in adjacent rows of the plurality of pixels. Synthesizing the respective signals from the first pixel type and the second pixel type may include adding respective digital pixel signals output from the pixel of the first pixel type and the pixel of the second pixel type of the first sub-pixel group. In some example embodiments, the image processing system may further include a second sub-pixel group of the pixel array. The second sub-pixel group may include four pixels including at least two pixels of the first pixel type and a pixel of the second pixel type. At least one pixel of the at least two pixels of the first pixel type may have a saturation time greater than another pixel of the at least two pixels of the first pixel type. Synthesizing the respective signals from the first pixel type and the second pixel type comprises adding respective digital pixel signals output from the at least two pixels of the first pixel type and the pixel of the second pixel type of the second sub-pixel group.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of image processing systems according to embodiments of the inventive concepts;

FIG. 2 illustrates a pixel array of FIG. 1 according to embodiments of the inventive concepts;

FIGS. 3A and 3B are cross-sectional views of examples of a pixel belonging to a sub-pixel group of a FIG. 2;

FIG. 4 is a graph illustrating a wide dynamic range that may be achieved when the pixel array illustrated in FIG. 2 is used;

FIG. 5 illustrates a pixel array of FIG. 1 according to other embodiments of the inventive concepts;

FIGS. 6A and 6B are cross-sectional views of examples of a pixel belonging to a sub-pixel group of FIG. 5;

FIG. 7 is a graph illustrating a wide dynamic range achieved when the pixel array illustrated in FIG. 5 is used; and

FIG. 8 is a block diagram of camera systems including an image sensor of FIG. 1 according to embodiments of the inventive concepts.

### DETAILED DESCRIPTION

The inventive concepts now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Expressions such as “at least one of” when preceding a list of elements, modify the entire list of elements and do not modify the individual elements of the list.

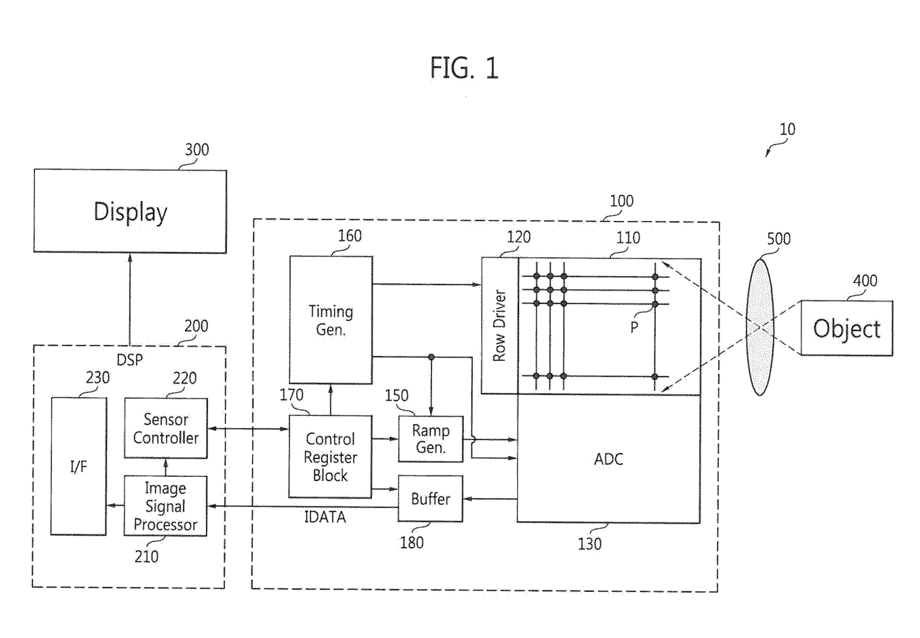

FIG. 1 is a block diagram of image processing systems 10 according to embodiments of the inventive concepts.

Referring to FIG. 1, the image processing system 10 may be a portable electronic device, e.g., a digital camera, a mobile phone, a smart phone, a tablet personal computer (PC), a personal digital assistant (PDA), a mobile internet device (MID), or a wearable computer, though the inventive concepts are not limited thereto. In some embodiments, the image processing system 10 may be a front camera, a rear camera, or other camera for use in a car.

The image processing system 10 may include a complementary metal-oxide semiconductor (CMOS) image sensor 100, a digital signal processor (DSP) 200, a display device 300, and an optical lens 500.

The CMOS image sensor 100 may include a pixel array 110, a row driver 120, an analog-to-digital converter (ADC) block 130, a ramp generator 150, a timing generator 160, a control register block 170, and a buffer 180.

The CMOS image sensor 100 may sense an image of an object 400 which is captured by (or which is incident on) the optical lens 500, and may generate image data IDATA corresponding to a result of sensing the image of the object 400. The CMOS image sensor 100 may be embodied as a front-side illumination (FSI) image sensor or a back-side illumination (BSI) image sensor.

The pixel array 110 may include a plurality of pixels P arranged in a matrix. The plurality of pixels P may transmit pixel signals to column lines.

The row driver 120 may drive the pixel array 110 in units of rows. The row driver 120 may transmit control signals for controlling operations of the plurality of pixels P to the pixel array 110, under control of the timing generator 160.

The ADC block 130 may compare pixel signals on which correlated double sampling (CDS) is performed with a ramp signal output from the ramp generator 150, output a plurality of comparison signals, respectively convert the plurality of comparison signals into digital pixel signals, and output the digital pixel signals to the buffer 180.

The timing generator 160 may control the row driver 120, the ADC block 130, and/or the ramp generator 150, based on output signals of the control register block 170.

The control register block 170 may store control bits for controlling operations of the timing generator 160, the ramp generator 150, and/or the buffer 180.

The buffer 180 may buffer the digital pixel signals output from the ADC block 130, and generate image data IDATA according to a result of buffering the digital pixel signals.

The DSP 200 may output image signals corresponding to the image data IDATA output from the CMOS image sensor 100 to the display device 300.

The DSP 200 may include an image signal processor (ISP) 210, a sensor controller 220, and an interface (I/F) unit 230.

In some embodiments, the image sensor 100 and the DSP 200 may be embodied as a chip and may form one package, e.g., a multi-chip package, together. In some embodiments, the image sensor 100 and the ISP 210 may be each embodied as a chip, and may form one package, e.g., a multi-chip package, together. In some embodiments, the image sensor 100 and the ISP 210 may be embodied as a chip together.

The ISP 210 may receive the image data IDATA output from the buffer 180, process (or handle) the image data IDATA such that the image data IDATA can be seen to human eyes, and output the processed (or handled) image data IDATA to the display device 300 via the I/F unit 230.

Also, the ISP 210 may add and/or combine at least two digital pixel signals among digital pixel signals corresponding to row lines and output from the buffer 180, and may output a result of adding the at least two digital pixel signals.

The sensor controller 220 may generate various control signals for controlling the control register block 170, under control of the ISP 210.

The I/F unit 230 may transmit image data processed by the ISP 210 to the display device 300.

The display device 300 may display the image data received from the I/F unit 230. For example, the display device 300 may be embodied as a thin-film transistor-liquid crystal display (TFT-LCD), a light-emitting diode (LED) display, an organic LED (OLED) display, or an active-matrix OLED (AMOLED) display.

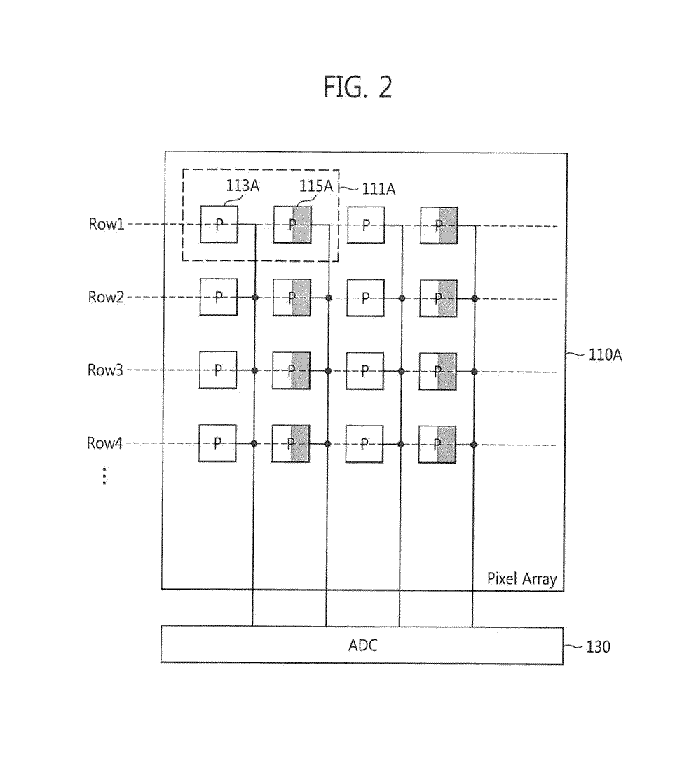

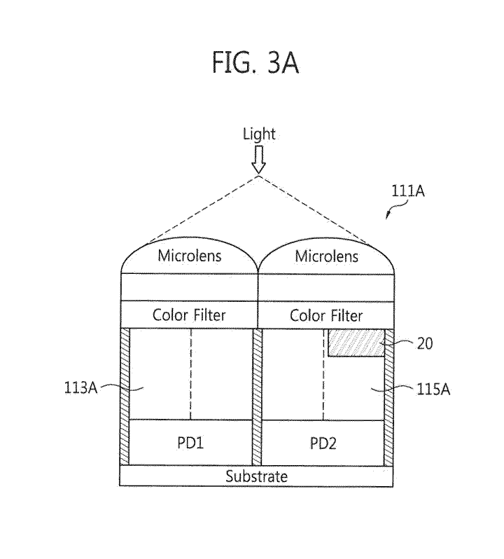

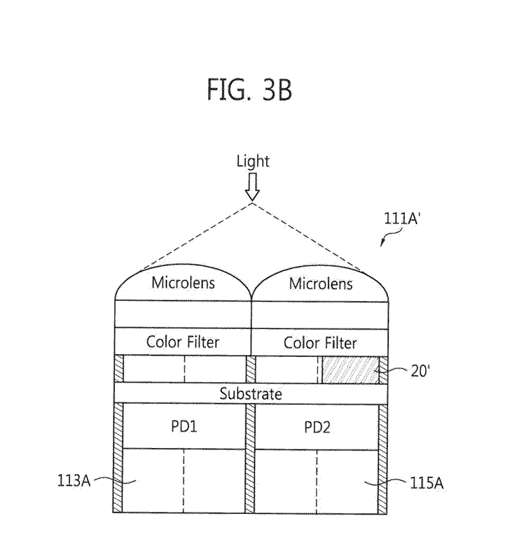

FIG. 2 illustrates a pixel array 110A, such as the pixel array 110 of FIG. 1, according to embodiments of the inventive concepts. FIGS. 3A and 3B are cross-sectional views of examples of a pixel belonging to a sub-pixel group of a FIG. 2.

Referring to FIGS. 1 and 2, the pixel array 110A may include a plurality of pixels P corresponding to a plurality of row lines. The plurality of pixels P may respectively include a plurality of photodiodes.

Each of the photodiodes included in the pixel army 110A may be an example of a photoelectric conversion device, and may be replaced with, for example, a phototransistor, a photogate, or a pinned-photodiode.

The plurality of photodiodes included in the plurality of pixels P may independently capture light or an image.

According to some embodiments, the pixel array 110A may include a plurality of sub-pixel groups each including at least two pixels among the plurality of pixels P corresponding to the plurality of row lines. Each of the plurality of sub-pixel groups may include two pixels corresponding to each of row lines or two pixels corresponding to adjacent row lines among the plurality of row lines.

In the present disclosure, a first sub-pixel group 111A will be described as an example. Although FIG. 2 illustrates that the first sub-pixel group 111A includes pixels corresponding to a first row line Row 1, example embodiments of the inventive concepts are not limited thereto and the first sub-pixel group 111A may include pixels respectively corresponding to adjacent row lines, e.g., first row line Row 1 and a second row line Row 2.

The first sub-pixel group 111A may include a first pixel 113A and a second pixel 115A. The first pixel 113A and the second pixel 115A may have different saturation times. To this end, a light-shielding film may be formed on the first pixel 113A or the second pixel 115A, as illustrated in FIGS. 3A and 3B. FIG. 3A is a cross-sectional view of a first sub-pixel group 111A when the image sensor 100 is an FSI image sensor. FIG. 3B is a cross-sectional view of a first sub-pixel group 111A′ when the image sensor 100 is a BSI image sensor.

Referring to FIG. 3A, in a first pixel 113A and a second pixel 115A belonging to the sub-pixel group 111A, photodiodes PD1 and PD2 may be formed on a silicon substrate and color filters may be formed on the photodiodes PD1 and PD2. A lens buffer or a planarization layer may be formed between micro-lens and the color filters.

The second pixel 115A may further include a light-shielding film 20 between the color filter and the photodiode PD2. Although FIG. 3A illustrates that the light-shielding film 20 is formed at a lower right portion of the color filter, the light-shielding film 20 may be formed at a lower left or central portion of the color filter to have an area corresponding to approximately 50% of the area of the photodiode PD2. In some embodiments, the light-shielding film 20 may be formed of a metal layer. Though a light-shielding film with 50% of the area of the photo diode is specifically disclosed, it will be understood that a light-shielding film with a larger or smaller area may be possible without departing from the inventive concepts. For example, a light-shielding film may be formed to have an area corresponding to 10% to 90% of the area of the photodiode.

Referring to FIG. 3B, in a first pixel 113A and a second pixel 115A belonging to the sub-pixel group 111A′, photodiodes PD1 and PD2 may be formed at the bottom of a silicon substrate and a light-shielding film 20′ may be formed between a color filter and the silicon substrate. In some embodiments, the light-shielding film 20′ may be formed of a metal layer to be used to form a wire-bonding pad.

Due to the above structure, light incident on the first sub-pixel group 111A and/or 111A′ may be accumulated in the photodiodes PD1 and PD2 of the first and second pixels 113A and 115A, and the first and second pixels 113A and 115A may output pixel signals according to the accumulated light.

Although FIGS. 3A and 3B illustrate that two micro-lenses are respectively located on the first pixel 113A and the second pixel 115A, example embodiments of the inventive concepts are not limited thereto, and one micro-lens may be located to correspond to the first pixel 113A and the second pixel 115A.

The ADC block 130 may convert a pixel signal output from the first sub-pixel group 111A into digital pixel signals, and may output the digital pixel signals to the ISP 210.

The ISP 210 may add and/or combine digital pixel signals corresponding to pixel signals output from the first pixel 113A and the second pixel 115A belonging to the first sub-pixel group 111A, and may output a result of adding the digital pixel signals.

That is, the ISP 210 may add and/or combine digital pixel signals of each sub-pixel group corresponding to one row line and may output a result of adding the digital pixel signals, or the ISP 210 may add and/or combine digital pixel signals of each sub-pixel group corresponding to adjacent row lines and may output a result of adding the digital pixel signals.

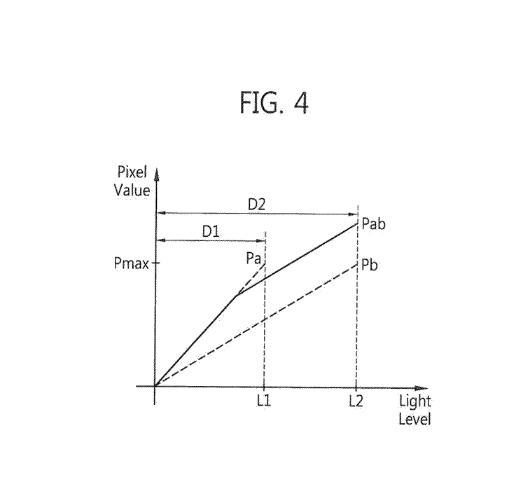

FIG. 4 is a graph illustrating a wide dynamic range that may be achieved when the pixel array 110A of FIG. 2 is used. Referring to FIGS. 2 to 4, a curve Pa denotes levels of a pixel signal corresponding to the first pixel 113A, and a curve Pb denotes levels of a pixel signal corresponding to the second pixel 115A. A curve Pab denotes levels of a pixel signal synthesized with respect to the first pixel 113A and the second pixel 115A.

At the same light level, a larger amount of light may be accumulated in the first pixel 113A than in the second pixel 115A. However, the first pixel 113A may saturate, as illustrated by Pmax in FIG. 4, at a first light level L1 and the second pixel 115A including the light-shielding film 20 may saturate at a second light level L2 which is higher than the first light level L1.

In some embodiments, when the pixel signals output from the first pixel 113A and the second pixel 115A are added together, the first pixel 113A and the second pixel 115A may saturate at the second light level L2 which is higher than the first light level L1 while a large amount of light is accumulated therein. Thus, a resultant dynamic range may be higher than a dynamic range D1 of the first pixel 113A and a dynamic range D2 of the second pixel 115A.

That is, an image obtained using the second pixel 115A may be synthesized even after the first pixel 113A saturates.

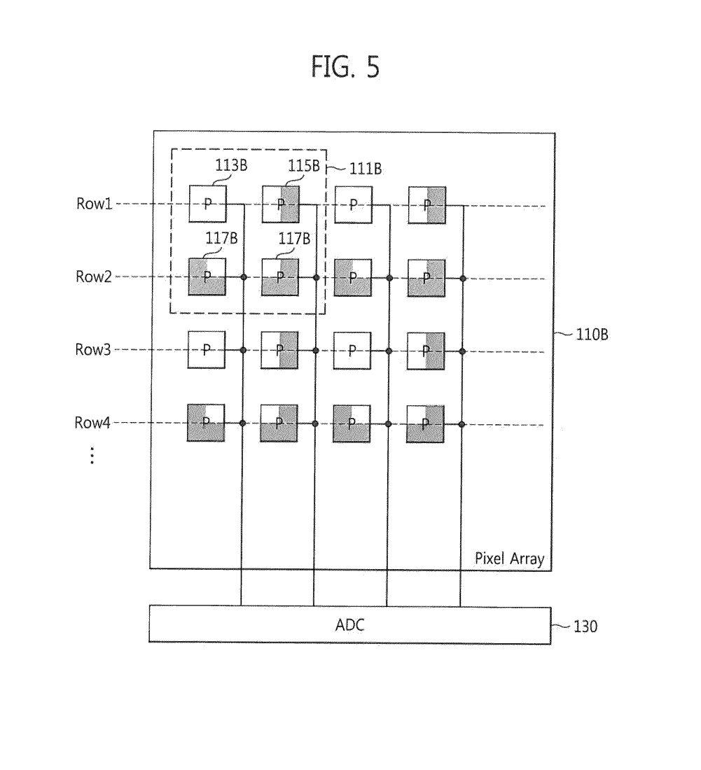

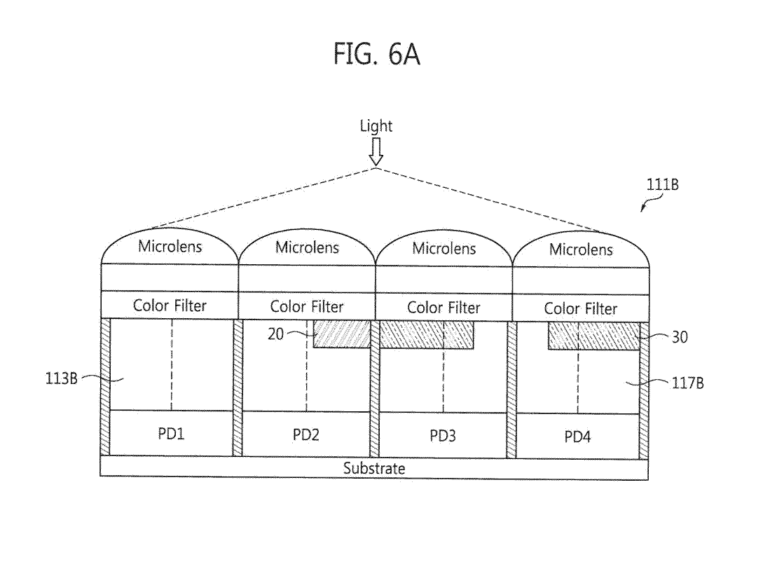

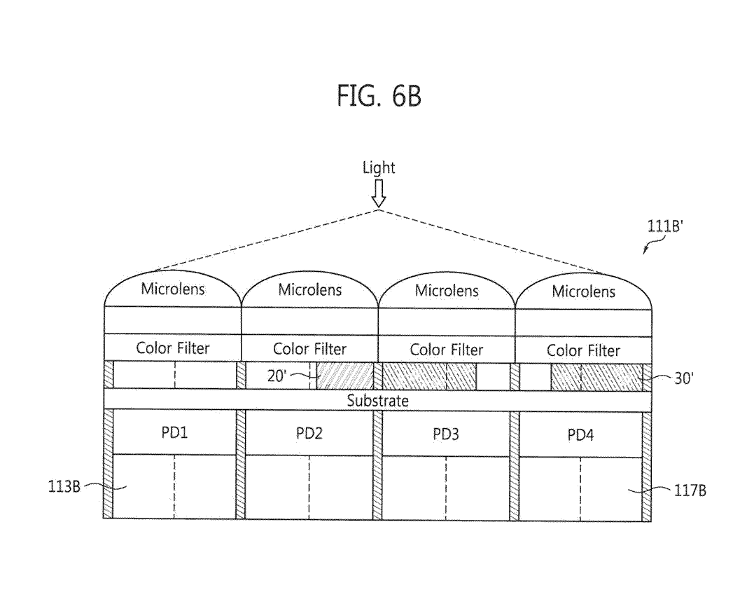

FIG. 5 illustrates a pixel array 110B, such as the pixel array 110 of FIG. 1, according to other embodiments of the inventive concepts. FIGS. 6A and 6B are cross-sectional views of examples of a pixel belonging to a sub-pixel group of FIG. 5.

Referring to FIGS. 1 and 5, the pixel array 110B according to other embodiments of the inventive concepts may include a plurality of sub-pixel groups each including at least two pixels among a plurality of pixels P corresponding to a plurality of row lines. Each of the plurality of sub-pixel groups may include four pixels respectively corresponding to adjacent row lines.

In the present disclosure, the first sub-pixel group 111B will be described as an example.

The first sub-pixel group 111B may include a first pixel 113B, a second pixel 115B, and third and fourth pixels 117B. The first pixel 113B to the fourth pixel 117B may have different saturation times. In some embodiments, the third and fourth pixels 117B may be configured to have the same saturation time.

To this end, a light-shielding film may be formed on at least two pixels among the first pixel 113B to the fourth pixel 117B, as illustrated in FIGS. 6A and 6B. FIG. 6A is a cross-sectional view of a first sub-pixel group 111B when the image sensor 100 is an FSI image sensor. FIG. 6B is a cross-sectional view of a first sub-pixel group 111B′ when the image sensor 100 is a BSI image sensor.

Referring to FIG. 6A, in a first pixel 113B to a fourth pixel 117B belonging to the sub-pixel group 111B, photodiodes PD1, PD2, PD3, and PD4 may be formed on a silicon substrate and color filters may be formed on the photodiodes PD1, PD2, PD3, and PD4. A lens buffer or a planarization layer may be formed between micro-lenses and the color filters.

The second pixel 115B may further include a first light-shielding film 20 between the color filter and the photodiode PD2. Each of the third and fourth pixels 117B may further include a second light-shielding film 30 between the color filter and the photodiode PD3 and/or PD4. In FIG. 6A, the first light-shielding film 20 and/or the second light-shielding film 30 may be formed of a metal layer.

Referring to FIG. 6B, in a first pixel 113B to a fourth pixel 117B belonging to the sub-pixel group 111B′, photodiodes PD1, PD2, PD3, and PD4 may be formed at the bottom of a silicon substrate, and a first light-shielding film 20′ and a second light-shielding film 30′ may be formed between color filters and the silicon substrate. In some embodiments, the first light-shielding film 20′ and/or the second light-shielding film 30′ may be each formed of a metal layer to be used to form a wire-bonding pad.

Similarly, FIGS. 6A and 6B illustrate that the first light-shielding films 20 and 20′ and the second light-shielding films 30 and 30′ may be formed at lower right or left portions of the color filters. However, each of the first light-shielding films 20 and 20′ and the second light-shielding films 30 and 30′ may be formed to have an area corresponding to approximately 50% of the area of the photodiode PD2 and/or an area corresponding to approximately 75% of the areas of the photodiodes PD3 and PD4.

That is, the second pixel 115B may have a longer saturation time than the first pixel 113B, and the third and fourth pixels 117B may have a longer saturation time than the second pixel 115B. Though light-shielding films with 50% and 75% of the area of the photo diodes are specifically disclosed, it will be understood that light-shielding films with larger or smaller areas may be possible without departing from the inventive concepts. For example, light-shielding films may be formed to have an area corresponding to 10% to 90% of the area of the photodiodes.

Due to the above structure, light incident on the first sub-pixel groups 111B and 111B′ may be accumulated in the photodiodes PD1, PD2, PD3, and/or PD4 of the first pixel 113B to the fourth pixel 117B, and the first pixels 113B to the fourth pixel 117B may output pixel signals according to the accumulated light.

Although FIGS. 6A and 6B illustrate that four micro-lenses are respectively located on the first pixel 113B to the fourth pixel 117B, example embodiments of the inventive concepts are not limited thereto and only one micro-lens may be located to correspond to the first pixel 113B to the fourth pixel 117B.

The ADC block 130 may convert a pixel signal output from the first sub-pixel groups 111B and 111B′ into digital pixel signals and may output the digital pixel signals to the ISP 210.

The ISP 210 may add and/or combine digital pixel signals corresponding to pixel signals output from the first pixel 113B to the fourth pixel 117B belonging to the first sub-pixel groups 111B and 111B′, and may output a result of adding the digital pixel signals.

That is, the ISP 210 may add and/or combine digital pixel signals of sub-pixel groups corresponding to adjacent row lines, and may output a result of adding the digital pixel signals.

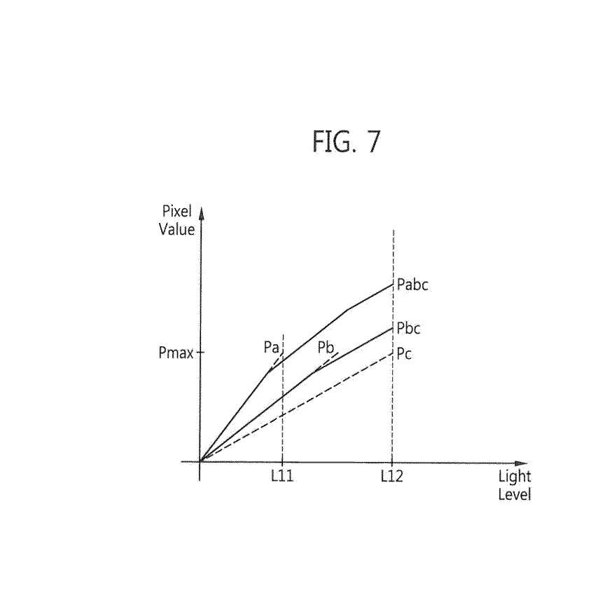

FIG. 7 is a graph illustrating a wide dynamic range that may be achieved when the pixel array 110B of FIG. 5 is used. Referring to FIGS. 5 to 7, a curve Pabc denotes levels of a pixel signal synthesized with respect to the first pixel 113B to the fourth pixel 117B. A curve Pbc denotes a level of a pixel signal synthesized with respect to the second pixel 115B to the fourth pixel 117B.

As illustrated in FIG. 7, when the pixel signals output from the first pixel 113B to the fourth pixel 117B are added together, the pixel signals output from the second pixel 115B to the fourth pixel 117B may added together to obtain an image until a second light level L12 arrives even after the first pixel 113B including no light-shielding film saturates at a first light level L11 (corresponding to Pmax).

Thus, an image sensor may be realized, in which a wide dynamic range is achieved by synthesizing images obtained using different exposure amounts by the pixel arrays 110A and 110B each including a plurality of sub-pixel groups.

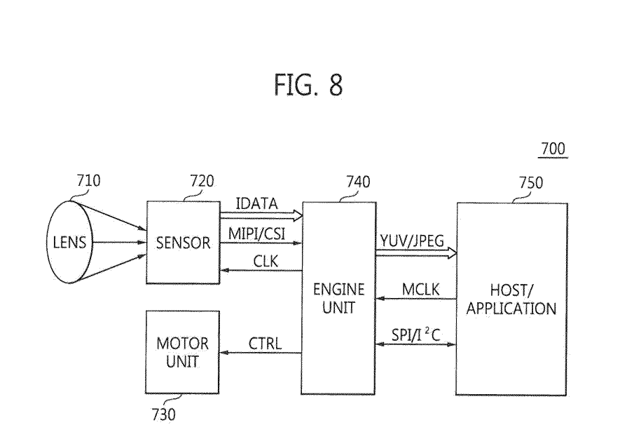

FIG. 8 is a block diagram of camera systems 700 including an image sensor 720, such as the image sensor 100 of FIG. 1, according to embodiments of the inventive concepts. Here, examples of the camera system 700 may include, for example, a front camera, a rear camera, or other camera for use in a car, though the inventive concepts are not limited thereto.

Referring to FIG. 8, the camera system 700 may include a lens 710, an image sensor 720, a motor unit 730, and an engine unit 740. The image sensor 720 may be substantially the same as the image sensor 100 described above with reference to FIGS. 1 to 7.

The lens 710 concentrates incident light on a light-receiving region (e.g., photodiode) of the image sensor 720.

The image sensor 720 may generate image data IDATA based on the light incident via the lens 710. The image sensor 720 may provide image data based on a clock signal CLK. In some embodiments, the image sensor 720 may interface with the engine unit 740 via a mobile industry processor interface (MIPI) and/or a camera serial interface (CSI).

The motor unit 730 may control a focus of the lens 710 or perform shuttering in response to a control signal CTRL received from the engine unit 740.

The engine unit 740 may control the image sensor 720 and the motor unit 730. In some embodiments, the engine unit 740 may generate YUV data YUV including information regarding a distance from an object, a luminance component, the difference between the luminance component and a blue component, and the difference between the luminance component and a red component, and/or may generate compressed data, e.g., Joint Photography Experts Group (JPEG) data, based on distance information and/or image data received from the image sensor 720. Though FIG. 8 illustrates the generation of YUV and/or JPEG data by the engine unit 740, other data formats are within the scope of the inventive concepts.

The engine unit 740 may be connected to a host/application 750. The engine unit 740 may provide the YUV data YUV or the JPEG data JPEG to the host/application 750, based on a master clock signal MCLK. Also, the engine unit 740 may interface with the host/application 750 through a serial peripheral interface (SPI) and/or an inter-integrated circuit (I²C).

According to one or more of the above example embodiments of the inventive concepts, image sensors and image processing systems including the image sensors may have a wide dynamic range by controlling an exposure amount by applying various light-shielding films to pixels.

While the inventive concepts have been particularly shown and described with reference to example embodiments thereof, it will be understood that various changes in form and details may be made therein without departing from the spirit and scope of the following claims.

What is claimed is:

1. An image sensor comprising:
a plurality of pixels;
a plurality of sub-pixel groups, respective ones of the sub-pixel groups including at least two pixels among the plurality of pixels; and
an analog-to-digital converter configured to perform analog-to-digital conversion on pixel signals output from the plurality of sub-pixel groups and configured to output digital pixel signals responsive to the analog-to-digital conversion,
wherein the at least two pixels have different saturation times.

2. The image sensor of claim 1, wherein the respective ones of the plurality of sub-pixel groups comprise a first pixel and a second pixel, and
wherein a first light-shielding film is in a portion of the first pixel.

3. The image sensor of claim 2, wherein the first pixel has a first saturation time longer than a second saturation time of the second pixel.

4. The image sensor of claim 3, wherein the first and second pixels further comprise:
a photoelectric conversion device;
a color filter on the photoelectric conversion device; and
a micro-lens on the color filter, and
wherein the first light-shielding film is between the color filter and the photoelectric conversion device of the first pixel.

5. The image sensor of claim 4, wherein the first light-shielding film has an area corresponding to 50% of an area of the photoelectric conversion device.

6. The image sensor of claim 1, wherein the respective ones of the plurality of sub-pixel groups comprise four pixels,
wherein a light-shielding film is in a portion of at least two pixels among the four pixels.

7. The image sensor of claim 6, wherein a first light-shielding film is on a first pixel of the four pixels and a second light-shielding film is on a second pixel of the four pixels, wherein the first pixel has a first saturation time longer than a second saturation time of the second pixel, and wherein the second saturation time of the second pixel is longer than saturation times of a third pixel and a fourth pixel of the four pixels.

8. The image sensor of claim 7, wherein each of the four pixels further comprises:
a photoelectric conversion device;
a color filter on the photoelectric conversion device; and
a micro-lens on the color filter,
wherein the first light-shielding film is between the color filter and the photoelectric conversion device of the first pixel, and
the second light-shielding film is between the color filter and the photoelectric conversion device of the second pixel.

9. The image sensor of claim 8, wherein the first light-shielding film has a first area corresponding to 75% of an area of the photoelectric conversion device of the first pixel, and
wherein the second light-shielding film has a second area corresponding to 50% of an area of the photoelectric conversion device of the second pixel.

10. An image processing system comprising:
an image sensor; and
an image signal processor configured to control the image sensor,
wherein the image sensor comprises:
a plurality of pixels arranged in a plurality of row lines;
a plurality of sub-pixel groups, wherein respective ones of the sub-pixel groups include at least two pixels among the plurality of pixels; and
an analog-to-digital converter configured to perform analog-to-digital conversion on pixel signals output from the plurality of sub-pixel groups and configured to output digital pixel signals responsive to the analog-to-digital conversion,
wherein the at least two pixels comprise a first pixel and a second pixel having different saturation times.

11. The image processing system of claim 10, wherein a first light-shielding film is in a portion of the first pixel.

12. The image processing system of claim 11, wherein the first pixel has a first saturation time that is longer than a second saturation time of the second pixel.

13. The image processing system of claim 12, wherein the image signal processor receives the digital pixel signals from the analog-to-digital converter, combines first digital pixel signals and second digital pixel signals corresponding to the first and second pixels respectively belonging to a sub-pixel group corresponding to one row line, and outputs a result of combining the digital pixel signals.

14. The image processing system of claim 10, wherein the respective ones of the plurality of sub-pixel groups comprise four pixels, and
wherein a light-shielding film is in a portion of at least two pixels among the four pixels.

15. The image processing system of claim 14, wherein a first light-shielding film and a second light-shielding film are respectively on a first pixel and a second pixel of the four pixels,
wherein a first area of the first light-shielding film is greater than a second area of the second light-shielding film,
wherein the first pixel has a first saturation time longer than a second saturation time of the second pixel, and
wherein the second saturation time of the second pixel is longer than saturation times of a third pixel and a fourth pixel of the four pixels.

16. An image processing system comprising:
an image sensor comprising a pixel array comprising a plurality of pixels; and
a digital signal processor configured to receive image data from the image sensor and output an image signal,
wherein the plurality of pixels in the pixel array comprise a first pixel type including a light-shielding film and a second pixel type free of a light-shielding film, and
wherein the digital signal processor is configured to synthesize respective signals from the first pixel type and the second pixel type to output the image signal.

17. The image processing system of claim 16, wherein the first pixel type has a first saturation time that is greater than a second saturation time of the second pixel type.

18. The image processing system of claim 17, wherein synthesizing the respective signals from the first pixel type and the second pixel type comprises adding respective digital pixel signals output from the first pixel type and the second pixel type.

19. The image processing system of claim 17, wherein the plurality of pixels are disposed in rows and columns and further comprising a first sub-pixel group of the pixel array, wherein the first sub-pixel group comprises a pixel of the first pixel type and a pixel of the second pixel type,
wherein the pixel of the first pixel type and the pixel of the second pixel type are in a same row or in adjacent rows of the plurality of pixels, and
wherein synthesizing the respective signals from the first pixel type and the second pixel type comprises adding respective digital pixel signals output from the pixel of the first pixel type and the pixel of the second pixel type of the first sub-pixel group.

20. The image processing system of claim 17, further comprising a second sub-pixel group of the pixel array, wherein the second sub-pixel group comprises four pixels including at least two pixels of the first pixel type and a pixel of the second pixel type,
wherein at least one pixel of the at least two pixels of the first pixel type has a saturation time greater than another pixel of the at least two pixels of the first pixel type, and
wherein synthesizing the respective signals from the first pixel type and the second pixel type comprises adding respective digital pixel signals output from the at least two pixels of the first pixel type and the pixel of the second pixel type of the second sub-pixel group.
